(19) United States
(12) Patent Application Publication
(10) Pub. No.: US 2025/0194303 A1
(43) Pub. Date: Jun. 12, 2025

(54) LIGHT-EMITTING ELEMENT AND MANUFACTURING METHOD OF THE LIGHT-EMITTING ELEMENT

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/053,507

(22) Filed: Feb. 14, 2025

Related U.S. Application Data
(63) Continuation of application No. PCT/JP2023/028862, filed on Aug. 8, 2023.

(30) Foreign Application Priority Data
Oct. 5, 2022 (JP) 2022-160638

(51) Int. Cl. H10H 20/825; H10H 20/01; H10H 20/815

(52) U.S. Cl. CPC H10H 20/825; H10H 20/01335; H10H 20/815

(57) ABSTRACT

A light-emitting element includes a substrate including amorphous glass, a first buffer layer, a second buffer layer, a gallium nitride layer, a stack, a cathode, and an anode. The first buffer layer is located over the substrate and contains aluminum and oxygen. The second buffer layer is located over the first buffer layer and contains aluminum and nitrogen. The gallium nitride layer is located over the second buffer layer. The stack is located over the gallium nitride layer and includes an n-type cladding layer, a p-type cladding layer, and an emission layer between the n-type cladding layer and the p-type cladding layer. The cathode and the anode are respectively located over the n-type cladding layer and the p-type cladding layer. Each of the n-type cladding layer, the p-type cladding layer, and the emission layer contains a Group 13 element and a Group 15 element.

### CROSS-REFERENCE TO RELATED APPLICATIONS

This application is a Continuation of International Patent Application No. PCT/JP2023/028862, filed on Aug. 8, 2023, which claims the benefit of priority to Japanese Patent Application No. 2022-160638, filed on Oct. 5, 2022, the entire contents of which are incorporated herein by reference.

### FIELD

An embodiment of the present invention relates to a semiconductor element exemplified by a light-emitting element and a transistor and a manufacturing method thereof. For example, an embodiment of the present invention relates to a semiconductor element including a gallium nitride-based semiconductor and a manufacturing method thereof.

### BACKGROUND

Typical examples of semiconductor elements include a light-emitting element and a transistor. In recent years, semiconductor devices containing nitrides of Group 13 elements such as gallium nitride (GaN) and indium nitride (InN) have been vigorously developed. Although such semiconductor devices have been fabricated using silicon or sapphire substrates so far, it is disclosed in Japanese Patent Application Publications No. 2019-41113, 2018-168029, and 2000-124140 that light-emitting elements and transistors having semiconductor layers containing nitrides of Group 13 elements can be formed on glass substrates.

### SUMMARY

An embodiment of the present invention is a light-emitting element. The light-emitting element includes a substrate including amorphous glass, a first buffer layer, a second buffer layer, a gallium nitride layer, a stack, a cathode, and an anode. The first buffer layer is located over the substrate and contains aluminum and oxygen. The second buffer layer is located over the first buffer layer and contains aluminum and nitrogen. The gallium nitride layer is located over the second buffer layer. The stack is located over the gallium nitride layer and includes an n-type cladding layer, a p-type cladding layer, and an emission layer between the n-type cladding layer and the p-type cladding layer. The cathode and the anode are respectively located over the n-type cladding layer and the p-type cladding layer. Each of the n-type cladding layer, the p-type cladding layer, and the emission layer contains a Group 13 element and a Group 15 element.

An embodiment of the present invention is a manufacturing method of a light-emitting element. The manufacturing method includes: forming a first buffer layer over a substrate containing amorphous glass; forming a second buffer layer over the first buffer layer; forming a gallium nitride layer over the second buffer layer with a sputtering method; forming a stack including an n-type cladding layer, a p-type cladding layer, and an emission layer between the n-type cladding layer and the p-type cladding layer over the gallium nitride layer with a sputtering method; and forming a cathode and an anode over the n-type cladding layer and the p-type cladding layer, respectively. Each of the n-type cladding layer, the p-type cladding layer, and the emission layer contains a Group 13 element and a Group 15 element.

An embodiment of the present invention is a display device including the plurality of the light-emitting elements described above.

An embodiment of the present invention is a transistor. The transistor includes a substrate containing amorphous glass, a first buffer layer, a second buffer layer, an active layer containing a Group 13 element and a Group 15 element, a gate insulating film, a gate electrode, a first terminal, and a second terminal. The first buffer layer is located over the substrate, and the second buffer layer is located over the first buffer layer. The active layer is located over the second buffer layer, and the gate insulating film is located over the active layer. The first terminal and the second terminal are located over and in contact with the active layer. The gate electrode is located over the active layer through the gate insulating film.

### BRIEF DESCRIPTION OF DRAWINGS

FIG. 1A is a schematic cross-sectional view of a light-emitting element according to an embodiment of the present invention.

FIG. 1B is a schematic cross-sectional view of a light-emitting element according to an embodiment of the present invention.

FIG. 2 is a diagram showing a relationship of lattice constants of components included in a light-emitting element according to an embodiment of the present invention.

FIG. 3A is a schematic cross-sectional view showing a manufacturing method of a light-emitting element according to an embodiment of the present invention.

FIG. 3B is a schematic cross-sectional view showing a manufacturing method of a light-emitting element according to an embodiment of the present invention.

FIG. 3C is a schematic cross-sectional view showing a manufacturing method of a light-emitting element according to an embodiment of the present invention.

FIG. 4A is a schematic cross-sectional view showing a manufacturing method of a light-emitting element according to an embodiment of the present invention.

FIG. 4B is a schematic cross-sectional view showing a manufacturing method of a light-emitting element according to an embodiment of the present invention.

FIG. 4C is a schematic cross-sectional view showing a manufacturing method of a light-emitting element according to an embodiment of the present invention.

FIG. 5A is a schematic cross-sectional view of a transistor according to an embodiment of the present invention.

FIG. 5B is a schematic cross-sectional view of a transistor according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

### First Embodiment

In this embodiment, a light-emitting element according to an embodiment of the present invention is explained. This light-emitting element is an inorganic light-emitting diode (LED) with a semiconductor layer containing a Group 13 element and a Group 15 element.

### 1. Structure

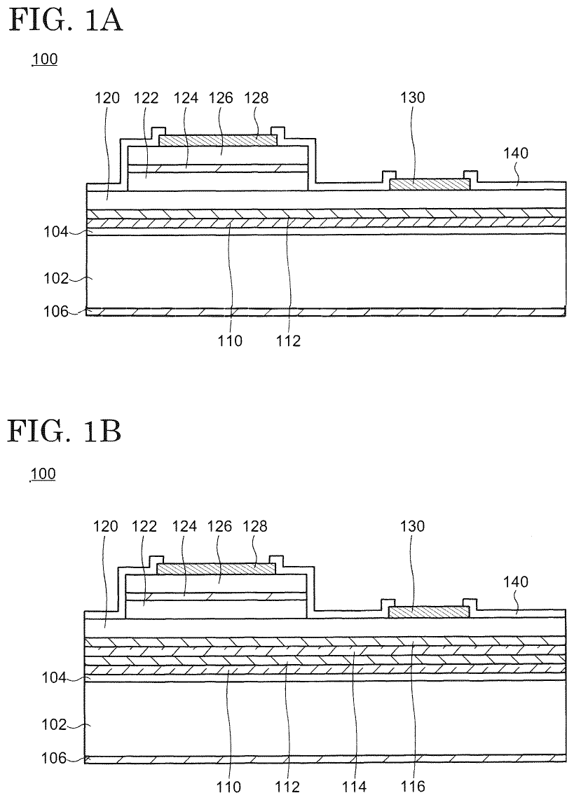

A schematic cross-sectional view of a light-emitting element 100 according to an embodiment of the present invention is shown in FIG. 1A. As shown in FIG. 1A, the light-emitting element 100 has a substrate 102 containing amorphous glass and two buffer layers (first buffer layer 110 and second buffer layer 112) over the substrate 102. The light-emitting element 100 further includes a gallium nitride layer 120 over and in contact with the second buffer layer 112 as well as a stack including an n-type cladding layer 122, a p-type cladding layer 126, and an emission layer 124 sandwiched between the n-type cladding layer 122 and the p-type cladding layer 126 over the gallium nitride layer 120. In addition, the light-emitting element 100 includes an anode 128 and a cathode 130 respectively provided over the p-type cladding layer 126 and the gallium nitride layer 120. The first buffer layer 110 may be in direct contact with the substrate 102 or may be provided over the substrate 102 through an overcoat 104 which is an optional component. When a potential difference equal to or higher than an emission threshold voltage is provided between the anode 128 and cathode 130, holes and electrons are respectively injected from the anode 128 and cathode 130 and recombine in the emission layer 124 to produce light emission.

The light-emitting element 100 may further include a protective film 140 over the anode 128 and cathode 130. Furthermore, the light-emitting element 100 may also have an undercoat 106 under the substrate 102. Hereinafter, these components are explained.

### (1) Substrate

The substrate 102 is a component for supporting the components fabricated thereover and includes amorphous glass. Preferably, a substrate with a high strain point and high surface flatness is used as the substrate 102. For example, the substrate 102 may have a strain point equal to or higher than 600° C. The substrate 102 may have a thickness sufficient to exhibit flexibility (e.g., equal to or greater than 0.1 mm and equal to or less than 0.5 mm) or a larger thickness (e.g., equal to or greater than 0.5 mm and equal to or less than 2 mm).

As an example, the substrate 102 is a glass substrate called alkali-free glass. In this case, the substrate 102 contains silicon dioxide, aluminum oxide, boron oxide, and an alkaline earth metal oxide such as calcium oxide and barium oxide. The content of the alkali metals such as sodium in the substrate 102 is preferred to be equal to or less than 0.1%.

### (2) Overcoat and Undercoat

The overcoat 104, which is an optional component, is provided over the substrate 102 so as to be in contact with the substrate 102. The overcoat 104 functions to prevent the diffusion of impurities such as trace amounts of alkali metal ions contained in the substrate 102 and is a single film or a stack of a plurality of films containing a silicon-containing inorganic compound such as silicon oxide and silicon nitride. The overcoat 104 is formed, for example, with a sputtering method or a chemical vapor deposition (CVD) method.

The undercoat 106 disposed under and in contact with the substrate 102 is a film having a function of inhibiting desorption of water or the like from the substrate 102 under high temperature conditions during the manufacture of the light-emitting element 100 as well as a function of preventing oxygen-containing impurities from entering the gallium nitride layer 120 structuring the light-emitting element 100 and the semiconductor layers provided thereover, such as the n-type cladding layer 122, the emission layer 124, and the p-type cladding layer 126. It also has a function of preventing warpage of the substrate 102 caused by the difference in thermal expansion coefficient between the substrate 102 and the gallium nitride layer 120. The undercoat 106 having these functions is configured so that its thermal expansion coefficient is between that of the substrate 102 and that of the gallium nitride layer 120. Specifically, the undercoat 106 is configured so that the thermal expansion coefficient is higher than 4.0×10⁻⁶/° C. and lower than 5.0×10⁻⁶/° C. For example, a film containing aluminum nitride, a film containing aluminum oxide, or a stack of these films can be used as the undercoat 106. The undercoat 106 may be formed by applying a sputtering method or the like.

### (3) First Buffer Layer and Second Buffer Layer

The first buffer layer 110 and the second buffer layer 112 are components for promoting crystallization of the gallium nitride layer 120 provided thereover. The first buffer layer 110 and the second buffer layer 112 also serve as films for improving adhesion to the substrate 102 so that deformation (warpage) of the substrate 102 as well as delamination of each layer provided thereover and generation of cracks are prevented under high temperature conditions during the manufacture of the light-emitting element 100. Therefore, the use of the first buffer layer 110 and the second buffer layer 112 prevents the generation of cracks in the gallium nitride layer 120 and the semiconductor layers provided thereover without deformation of the substrate 102 and the gallium nitride layer 120, or the like and also improves the crystallinity of these layers.

### (a) First Buffer Layer

The first buffer layer 110 is provided over the substrate 102 directly or through the overcoat 104. The first buffer layer 110 includes an inorganic compound containing aluminum and oxygen, specifically aluminum oxide. The first buffer layer 110 may include aluminum oxide (aluminum oxynitride) including nitrogen in addition to aluminum and oxygen. For example, the composition of the first buffer layer 110 may be represented by AlₓO_{y} (Formula 1), where y/x may be equal to or more than 1.4 and equal to or less than 1.6 in Formula 1. Alternatively, the composition of the first buffer layer 110 may be represented by AlₓO_{y}N_{z} (Formula 2). In Formula 2, (2y+3z)/3x may be equal to or greater than 0.9 and equal to or less than 1.1, and z/y may be equal to or greater than 0.05 and equal to or less than 0.2. When the first buffer layer 110 includes aluminum oxide or aluminum oxide containing nitrogen, the first buffer layer 110 is able to create a strong bond with aluminum oxide included in the substrate 102 containing amorphous glass. Thus, delamination between the substrate 102 and the first buffer layer 110 is effectively suppressed. Note that the composition of the first buffer layer 110 may be constant in the film thickness direction, or the oxygen concentration may decrease with increasing distance from the substrate 102 (i.e., as it approaches the second buffer layer 112). The formation of the first buffer layer 110 with a lower oxygen concentration at the top surface allows the reduction of the oxygen concentration in the second buffer layer 112 in contact with the first buffer layer 110.

In order to allow the second buffer layer 112 formed over the first buffer layer 110 to grow in the c-axis direction more effectively, the surface of the first buffer layer 110 preferably has high planarity. It is also preferred to form the first buffer layer 110 with a relatively small thickness so that it has high crystallinity and stress caused by the difference in thermal expansion coefficients from adjacent components (substrate 102 and second buffer layer 112) is reduced to prevent defects such as delamination and cracks. Specifically, the thickness of the first buffer layer 110 is preferred to be equal to or less than 50 nm, and the first buffer layer 110 is formed with a thickness equal to or greater than 2 nm and equal to or less than 50 nm, for example.

### (b) Second Buffer Layer

The second buffer layer 112 is provided over and in contact with the first buffer layer 110. The second buffer layer 112 includes an inorganic compound containing aluminum and nitrogen such as aluminum nitride. For example, the composition of the second buffer layer 112 may be represented by AlₓN_{y} (Formula 3), where x/y may be equal to or greater than 0.9 and equal to or less than 1.1 in Formula 3. Although the second buffer layer 112 may contain oxygen, its concentration (e.g., the average concentration of oxygen in the second buffer layer 112) is lower than that of the first buffer layer 110. The composition of the second buffer layer 112 may also be constant in the thickness direction, or the nitrogen concentration may increase or decrease with increasing distance from the first buffer layer 110 (i.e., as it approaches the gallium nitride layer 120). Alternatively, the nitrogen concentration may vary in the film thickness direction so that the ratio of x to y (x/y) in Formula 3 approaches 1 with increasing distance from the first buffer layer 110. The composition of the second buffer layer 112 is preferred to be substantially AlN (i.e., x and y are identical or substantially identical) at the top surface of the second buffer layer 112 in contact with the gallium nitride layer 120.

Similar to the first buffer layer 110, the surface of the second buffer layer 112 is also preferred to have high flatness in order to allow the gallium nitride layer 120 formed over the second buffer layer 112 to grow in the c-axis direction more effectively. In addition, it is preferred to form the second buffer layer 112 with a thickness equal to or greater than 20 nm and equal to or less than 100 nm, for example, in order to have high crystallinity and to reduce stress caused by the difference in thermal expansion coefficients from adjacent components (first buffer layer 110 and gallium nitride layer 120) to suppress the generation of defects such as cracks.

Since the second buffer layer 112 may contain aluminum nitride as described above, the second buffer layer 112 is capable of having a hexagonal close-packed structure, a face-centered cubic structure, or an equivalent structure thereto. Here, the hexagonal close-packed structure or the equivalent structure thereto includes a crystal structure in which the c-axis is not orthogonal to the a-axis and the b-axis. Thus, in this structure, the second buffer layer 112 orients in the (0001) direction, that is, the c-axis direction, with respect to the surface thereof. In addition, the second buffer layer 112 having the face-centered cubic structure or its equivalent structure orients in the (111) direction with respect to the surface thereof. Therefore, the c-axis of the second buffer layer 112 orients in a direction perpendicular or substantially perpendicular to the surface on which the second buffer layer 112 is provided (i.e., the top surface of the first buffer layer 110). As described below, the second buffer layer 112 as well as the gallium nitride layer 120, the n-type cladding layer 122, the emission layer 124, and the p-type cladding layer 126 provided thereover includes semiconductors containing a Group 13 element and a Group 15 element, such as gallium nitride, and it has been known that gallium nitride takes a hexagonal close-packed structure and undergoes crystal growth in the c-axis direction to minimize its surface energy. Therefore, the formation of the gallium nitride layer 120 over the second buffer layer 112 promotes the crystal growth of not only the gallium nitride layer 120 but also the semiconductor layers formed thereover in the c-axis direction. As a result, the crystallinity of these layers is improved, and excellent characteristics as light-emitting elements can be obtained.

### (c) Thermal Expansion Coefficients of First Buffer Layer and Second Buffer Layer

The thermal expansion coefficients of the first buffer layer 110 and the second buffer layer 112 having the aforementioned structures each fall between the thermal expansion coefficient of the substrate 102 and the thermal expansion coefficient of the gallium nitride layer 120. Specifically, it has been known that the thermal expansion coefficient of the substrate 102 containing amorphous glass is 3.5×10⁻⁶/° C. to 3.9×10⁻⁶/° C., and that the thermal expansion coefficient of gallium nitride included in the gallium nitride layer 120 in the in-plane direction (the direction parallel to the top surface of the substrate 102 which is the a-axis direction. The same is applied hereinafter.) is 5.6×10⁻⁶/° C. On the other hand, the thermal expansion coefficient of the first buffer layer 110 in the in-plane direction depends on the composition and is equal to or greater than 3.5×10⁻⁶/° C. and equal to or less than 5.6×10⁻⁶/° C. Similarly, the thermal expansion coefficient of the second buffer layer 112 in the in-plane direction also depends on its composition and is equal to or greater than 3.6×10⁻⁶/° C. and equal to or less than 4.6×10⁻⁶/° C. Therefore, in the light-emitting element 100, the thermal expansion coefficient in the in-plane direction can be changed (increased) stepwise in the direction from the substrate 102 to the gallium nitride layer 120, and there is no large difference in thermal expansion coefficient between adjacent components. As a result, large stresses do not occur under high temperature conditions during the manufacture of the light-emitting element 100, and delamination between adjacent components and crack generation in each layer can be effectively prevented.

### (d) Lattice Constants of First Buffer Layer and Second Buffer Layer

Since amorphous glass does not have a clear crystal structure unlike crystalline glass (e.g., quartz), the lattice constant is not generally defined. However, it can be considered that the crystal structure of silicon oxide which is its main component determines the crystallinity of the first buffer layer 110 provided over the substrate 102. Therefore, in the specification, the value 0.491 nm calculated from the broad peak of 2θ around 22° in the X-ray diffraction of amorphous glass is employed as the lattice constant of the substrate 102 in the a-axis direction. It has been known that the lattice constant in the a-axis direction of gallium nitride included in the gallium nitride layer 120 is 0.318 nm. In contrast, the lattice constants in the a-axis direction of the first buffer layer 110 and the second buffer layer 112 having the aforementioned structures each depend on their composition, and the former is equal to or greater than 0.355 nm and equal to or less than 0.480 nm, while the latter is equal to or greater than 0.300 nm and equal to or less than 0.330 nm.

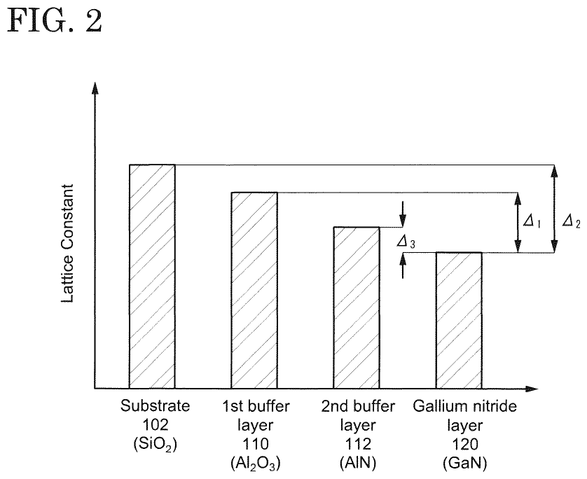

Therefore, the relationship of lattice constants among the substrate 102, the first buffer layer 110, the second buffer layer 112, and the gallium nitride layer 120 is schematically represented in FIG. 2. As can be understood from FIG. 2, the lattice constants in the a-axis direction decrease stepwise in the order of the substrate 102, the first buffer layer 110, the second buffer layer 112, and the gallium nitride layer 120 in the light-emitting element 100. Therefore, the difference (Δ₁) in lattice constant in the a-axis direction between the first buffer layer 110 containing aluminum oxide and the gallium nitride layer 120 containing gallium nitride is smaller than that (Δ₂) between the substrate 102 containing amorphous glass and the gallium nitride layer 120. Furthermore, the difference (Δ₃) in lattice constant in the a-axis direction between the second buffer layer 112 containing aluminum nitride and the gallium nitride layer 120 is smaller than that (Δ₂) between the substrate 102 and the gallium nitride layer 120 and that (Δ₁) between the first buffer layer 110 and the gallium nitride layer 120.

Because the difference Δ₃ in lattice constant in the a-axis direction between the second buffer layer 112 and the gallium nitride layer 120 is small, the crystal structure of the gallium nitride layer 120 formed over the second buffer layer 112 is readily affected by the second buffer layer 112. Therefore, when the second buffer layer 112 orients highly in the c-axis-direction, the gallium nitride layer 120 is also effectively promoted to crystallize in the c-axis direction. However, when the second buffer layer 112 has low crystallinity, the gallium nitride layer 120 cannot be sufficiently crystallized, causing a decrease in crystallite size.

As can be understood from FIG. 2, the difference Δ₂ between the lattice constant of the substrate 102 and the lattice constant of the second buffer layer 112 is large, and the crystal growth of the second buffer layer 112 is inhibited due to the large lattice constant difference when the second buffer layer is formed directly over the substrate 102. However, the formation of the first buffer layer 110 with a lattice constant between the substrate 102 and the second buffer layer 112 mitigates the lattice constant mismatch between the substrate 102 and the second buffer layer 112 so that the crystallization of the buffer layer 112 can be promoted by forming the second buffer layer 112 over the first buffer layer 110. As a result, the second buffer layer 112 with improved crystallinity can be obtained, and the crystallinity of the gallium nitride layer 120 in the c-axis direction can be improved by forming the gallium nitride layer 120 thereover. Since the crystallinity of the semiconductor layers provided over the gallium nitride layer 120 can also be improved with this process, the light-emitting element 100 with excellent characteristics can be produced.

### (4) Gallium Nitride Layer

The gallium nitride layer 120 contains gallium nitride. Although the addition of a dopant to gallium nitride provides p-type or n-type conductivity, the gallium nitride layer 120 may be an undoped gallium nitride layer containing no dopant. Alternatively, the gallium nitride layer 120 may contain n-type gallium nitride with a dopant imparting n-type conductivity (such as silicon and germanium) or p-type gallium nitride with a dopant imparting p-type conductivity (such as magnesium, zinc, cadmium, and beryllium).

### (5) N-Type Cladding Layer, Emission Layer, and P-Type Cladding Layer

The n-type cladding layer 122, the emission layer 124, and the p-type cladding layer 126 are configured to emit visible light when the holes and the electrons respectively injected from the anode 128 and the cathode 130 are recombined. The n-type cladding layer 122, the emission layer 124, and the p-type cladding layer 126 may each have a single layer structure or a stacked structure in which a plurality of layers is stacked. Note that although the n-type cladding layer 122, the emission layer 124, and the p-type cladding layer 126 are stacked in order from the substrate 102 side in the example shown in FIG. 1A, the semiconductor layers may be configured in the reverse order of this sequence. In this case, the gallium nitride layer 120 is configured to contain undoped gallium nitride or p-type gallium nitride, over which the p-type cladding layer 126, the emission layer 124, and the n-type cladding layer 122 are formed.

The n-type cladding layer 122, the emission layer 124, and the p-type cladding layer 126 are each a semiconductor layer containing a Group 13 element and a Group 15 element. Specifically, a semiconductor containing aluminum, gallium, and/or indium as well as nitrogen, phosphorus, and/or arsenic is included in these layers. Gallium-based materials are represented as a typical semiconductor. For example, gallium nitride-based materials such as gallium nitride, aluminum gallium nitride (AlGaN), and indium gallium nitride (InGaN), and gallium phosphide-based materials such as gallium phosphide (GaP) and aluminum indium gallium phosphide (AlGaInP) are represented. The aforementioned dopants may further be included in the n-type cladding layer 122 and the p-type cladding layer 126. The addition of dopants enables valence electron control and band gap control of each layer. Note that the compositions of the gallium nitride layer 120 and the layer provided over and in contact therewith (n-type cladding layer 122 in the example shown in FIG. 1A) may be identical.

The emission layer 124 may have a single-layer structure of indium gallium nitride or may have a quantum well structure, for example. A quantum well structure is a structure in which a plurality of layers with different band gaps and thicknesses of approximately 1 to 5 nm is alternately stacked. For example, an alternating stack of indium gallium nitride and gallium nitride, an alternating stack of indium gallium phosphide arsenide (GaInAsP) and indium phosphide (InP), an alternating stack of aluminum indium arsenide (AlInAs) and indium gallium arsenide (InGaAs) are exemplified.

### (6) Anode and Cathode

The anode 128 and the cathode 130 respectively inject holes and electrons into the p-type cladding layer 126 and the n-type cladding layer 122. As the anode 128, a film of a metal such as palladium and gold, an alloy of these metals, or a conductive oxide transmitting visible light such as indium-tin mixed oxide (ITO) and indium-zinc mixed oxide (IZO) may be used, for example. A metal such as aluminum, titanium, gold, silver and indium or an alloy of these metals may be used for the cathode 130. Both the anode 128 and the cathode 130 may have a single-layer structure or may be a stack of a plurality of films with different compositions.

### (7) Protective Film

The protective film 140 is a component for preventing impurities such as oxygen and water from entering the light-emitting element 100 and is composed of one or a plurality of films containing a silicon-containing inorganic compound such as silicon oxide and silicon nitride, for example. The protective film 140 is provided with openings to expose the anode 128 and the cathode 130, and wirings which are not illustrated are electrically connected to the anode 128 and cathode 130 using these openings.

As described above, in the light-emitting element 100, the first buffer layer 110 and the second buffer layer 112 are stacked over the substrate 102 containing amorphous glass, over which the gallium nitride layer 120 is provided. Since the substrate 102 and the first buffer layer 110 contain aluminum oxide, a strong bond is obtained therebetween. In addition, since the thermal expansion coefficient increases stepwise from the first buffer layer 110 to the gallium nitride layer 120 and there is no large difference in thermal expansion coefficient between adjacent components, delamination and crack generation under high temperature conditions can be prevented.

Furthermore, the large lattice mismatch between the substrate 102 and the second buffer layer 112 can be mitigated because the first buffer layer 110 having the lattice constant between those of the substrate 102 and the second buffer layer 112 is provided between the substrate 102 and the second buffer layer 112 where a large lattice constant difference exists. Therefore, compared with a case where the second buffer layer 112 is directly provided over the substrate 102, the crystallinity of the second buffer layer 112 can be significantly improved by providing the second buffer layer 112 over the first buffer layer 110 having high bonding strength with the substrate 102. As a result, the crystallinity of the n-type cladding layer 122, the emission layer 124, and the p-type cladding layer 126, which determine the function as the light-emitting element 100, is improved, which allows the production of a light-emitting element with excellent characteristics.

Moreover, since aluminum oxide, aluminum oxynitride, and aluminum nitride included in the first buffer layer 110 and second buffer layer 112 are highly resistant to various types of etchants used in the photolithography process, they are not lost or damaged in the manufacturing process of the light-emitting element 100 described below. Therefore, a highly reliable light-emitting element 100 can be manufactured using a variety of apparatus used for manufacturing conventional semiconductor devices.

### 2. Modified Example

The structure of the light-emitting element 100 is not limited to the structure described above. Specifically, three or more buffer layers may be provided between the substrate 102 and the gallium nitride layer 120. For example, a third buffer layer 114 over the second buffer layer 112 and a fourth buffer layer 116 over the third buffer layer 114 may be provided in addition to the first buffer layer 110 and the second buffer layer 112 as shown in FIG. 1B. Adjacent buffer layers are provided so as to be in contact with each other.

The structures of the third buffer layer 114 and the fourth buffer layer 116 may be identical to the structures of the first buffer layer 110 and the second buffer layer 112, respectively. Alternatively, each of the first buffer layer 110 to the fourth buffer layer 116 may contain aluminum oxide, aluminum oxynitride, or aluminum nitride, and the oxygen concentration and the nitrogen concentration may respectively decrease and increase in the order from the first buffer layer 110 to the fourth buffer layer 116. In this case, the fourth buffer layer 116 preferably includes aluminum nitride.

In this modified example, the lattice mismatch between the buffer layer in contact with the gallium nitride layer 120 and the substrate 102 can be mitigated, and the difference in thermal expansion coefficient between adjacent components can be reduced. Therefore, a highly crystalline gallium nitride layer 120 can be formed, and delamination and crack generation can be suppressed.

### Second Embodiment

In this embodiment, a manufacturing method of the light-emitting element 100 is explained. An explanation of the structures the same as or similar to those described in the First Embodiment may be omitted.

### (1) Formation of Overcoat and Undercoat

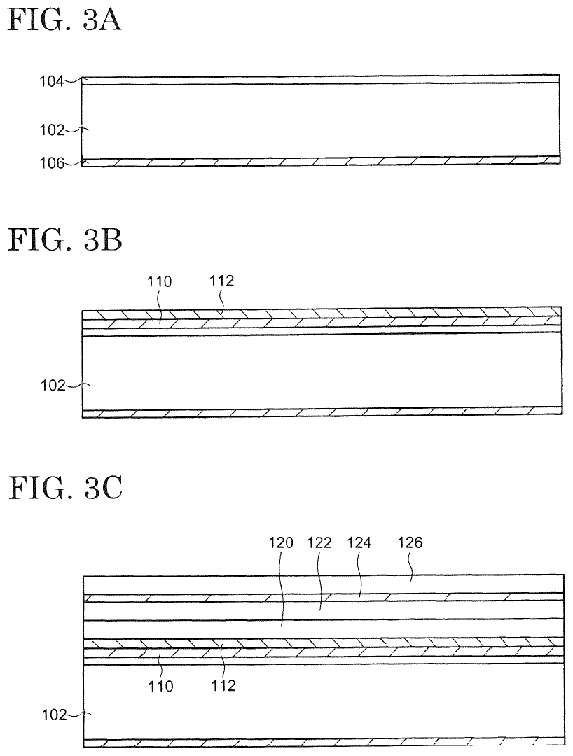

First, the overcoat 104 and the undercoat 106 are respectively formed over and under the substrate 102 as shown in FIG. 3A. There is no restriction on the size of the substrate 102, and a large amorphous glass substrate, also called mother glass, can be used as the substrate 102. For example, an amorphous glass substrate with a 600 mm×720 mm size called 3.5 generation glass, an amorphous glass substrate with 730 mm×920 mm size called 4.5 generation glass, an amorphous glass substrate with 1500 mm×1850 mm size called 6th generation glass, or a larger size may be used. Thus, a single substrate 102 can be used to manufacture a plurality of light-emitting elements 100, which contributes to a reduction of the manufacturing cost of the light-emitting element 100. The overcoat 104 and the undercoat 106 may be formed using a CVD method or a sputtering method. Since the overcoat 104 and the undercoat 106 are optional components, one or both of them may not be formed.

### (2) Formation of First Buffer Layer

Next, the first buffer layer 110 is formed over the substrate 102 (FIG. 3B). The first buffer layer 110 may be formed by a sputtering method. When the first buffer layer 110 contains aluminum oxide, aluminum or aluminum oxide may be used as a target, and oxygen radicals may be applied during reactive sputtering using a mixture of argon and oxygen to form the first buffer layer 110, for example. Alternatively, an aluminum oxide target may be sputtered with argon, and an oxygen radical treatment may further be performed on the resulting first buffer layer 110. Alternatively, the first buffer 110 may be formed by irradiating the substrate 102 with oxygen plasma to form an oxygen-excessive layer on the surface of the substrate 102, sputtering an aluminum target to form a thin aluminum film thereover, and performing heating (annealing) to convert the thin aluminum film to an aluminum oxide film. Alternatively, the first buffer layer 110 may be formed by sputtering an aluminum target using argon or a mixed gas of argon and oxygen to form a thin aluminum film or a thin aluminum film containing aluminum oxide over the substrate 102, followed by oxidizing aluminum with an oxygen-plasma treatment or an oxygen-radical treatment.

When the first buffer layer 110 contains aluminum oxide including nitrogen, the first buffer layer 110 may be formed with reactive sputtering of an aluminum target or an aluminum oxide target using a mixed gas of argon, oxygen, and nitrogen, for example. At this time, an oxygen-radical treatment and/or a nitrogen-radical treatment may be performed on the resulting first buffer layer 110. Alternatively, the first buffer layer 110 may be formed with reactive sputtering of an aluminum oxide target using a mixed gas of argon and nitrogen. Alternatively, the first buffer layer 110 may be formed by sputtering an aluminum oxynitride target using argon. Alternatively, the first buffer layer 110 may be formed by irradiating the substrate 102 with nitrogen dioxide plasma to oxynitride the surface of the substrate 102, sputtering an aluminum target to form a thin aluminum film, and then performing annealing to oxynitride the aluminum. Alternatively, a thin aluminum film may be formed by sputtering an aluminum target with argon, and then the thin aluminum film may be oxynitrated using oxygen and nitrogen plasma. Alternatively, the first buffer layer 110 may be formed by sputtering an aluminum target, an aluminum oxynitride target, or an aluminum oxide target with argon and simultaneously performing an oxygen radical treatment and nitrogen radical irradiation.

As mentioned above, the first buffer layer 110 may be configured such that the oxygen concentration decreases with increasing distance from the substrate 102. This configuration allows the formation of aluminum oxide closer to the stoichiometric ratio at the top surface of the first buffer layer 110. In this case, the oxygen partial pressure may be reduced along with the film growth in reactive sputtering using a mixed gas of argon and oxygen, for example.

After forming the first buffer layer 110, annealing may be performed to promote crystallization and increase the density of the layer. The temperature at this time may be selected from a range equal to or higher than 500° C. and equal to or lower than 700° C., for example.

### (3) Formation of Second Buffer Layer

Next, the second buffer layer 112 is formed over the first buffer layer 110 (FIG. 3B). The second buffer layer 112 may also be formed by sputtering. For example, the second buffer layer 112 can be formed by sputtering an aluminum nitride target with argon. Alternatively, the second buffer layer 112 may be formed by performing reactive sputtering on an aluminum target or an aluminum nitride target using a mixed gas of argon and nitrogen. At this time, a nitrogen radical treatment may further be performed on the resulting second buffer layer 112. Alternatively, the second buffer layer 112 may be formed by sputtering an aluminum target or an aluminum nitride target with argon and simultaneously performing irradiation with nitrogen radicals.

As mentioned above, the nitrogen concentration may also vary in the second buffer layer 112 in the film thickness direction. For example, the nitrogen concentration may be controlled by controlling the partial pressure of nitrogen in reactive sputtering, or the nitrogen concentration on the surface of the second buffer layer 112 may be increased by a nitrogen radical treatment.

Similar to the first buffer layer 110, annealing may be performed on the second buffer layer 112 to promote crystallization and increase the density of the layer. The temperature at this time may be selected from a range equal to or higher than 500° C. and equal to or lower than 700° C., for example.

Note that the first buffer layer 110 and the second buffer layer 112 are preferably formed continuously in the same chamber or in separate chambers while maintaining a vacuum state without retrieving atmospheric conditions. This process prevents impurities from entering the interface between the first buffer layer 110 and the second buffer layer 112 and more effectively promotes the crystallization of the second buffer layer 112.

### (4) Formation of Gallium Nitride Layer, N-Type Cladding Layer, Emission Layer, and P-Type Cladding Layer

Then, the gallium nitride layer 120 is formed over the second buffer layer 112, over which the semiconductor layers, i.e., the n-type cladding layer 122, the emission layer 124, and the p-type cladding layer 126 are sequentially formed (FIG. 3C). Each of these layers can also be formed using a sputtering method. For example, these layers may be formed by sputtering semiconductor targets such as gallium nitride with argon in the presence of plasma. When a dopant is contained in the layers, a target containing a dopant may be used.

Alternatively, a gallium nitride target and a target for dopants may simultaneously be sputtered. In addition, the emission layer 124 with alternating layers of indium gallium nitride films and gallium nitride films can be formed by using an indium gallium nitride target and a gallium nitride target. Alternatively, the emission layer 124 in which indium gallium nitride films and gallium nitride films are alternatively stacked can be formed by simultaneously sputtering a gallium nitride target and an indium target when the emission layer 124 is an indium gallium nitride film or by sputtering the gallium nitride target when the gallium nitride film is formed.

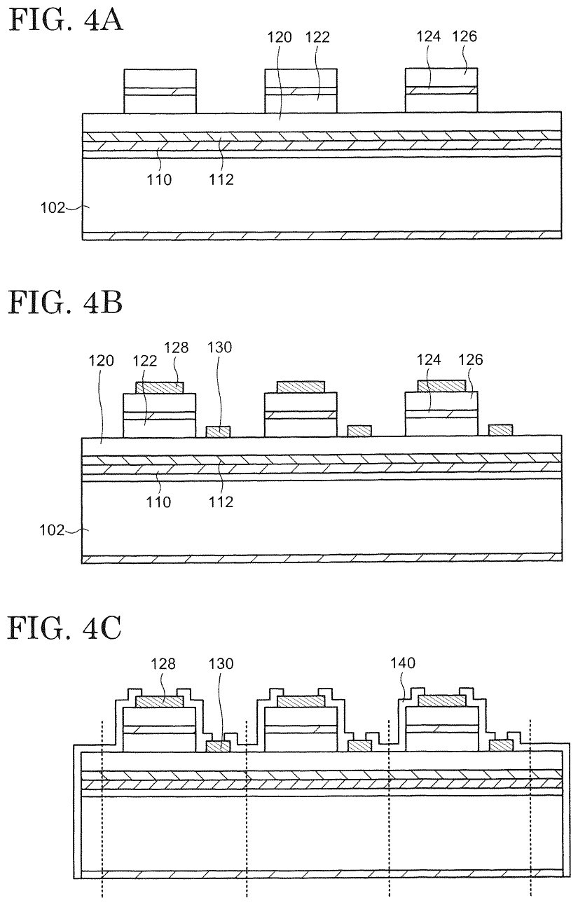

Next, the n-type cladding layer 122 to the p-type cladding layer 126 are patterned. The patterning is performed so that the plurality of stacked bodies including the n-type cladding layer 122, the emission layer 124, and the p-type cladding layer 126 is arranged in an island shape over the gallium nitride layer 120 as shown in FIG. 4A. Since each stacked body constitutes one light-emitting element 100, the plurality of light-emitting elements 100 sharing the gallium nitride layer 120 can be formed over a single substrate 102. Since the patterning can be performed by applying known photolithography, a detailed description is omitted.

After that, the anode 128 and the cathode 130 are respectively formed over the p-type cladding layer 126 and the n-type cladding layer 122 (FIG. 4B). The anode 128 and the cathode 130 may be formed using a vacuum evaporation method, an electron beam evaporation method, a CVD method, a sputtering method, or the like. When the protective film 140 is provided, one or a plurality of films containing a silicon-containing inorganic compound may be formed to cover the anode 128 and cathode 130 using a CVD method or a sputtering method, and then the protective film 140 may be etched to expose a portion of the anode 128 and the cathode 130. Hence, the protective film 140 is also formed over the side surfaces of the substrate 102 (FIG. 4C).

After that, the substrate 102 is divided along the dotted line in FIG. 4C, thereby providing the light-emitting element 100 shown in FIG. 1A.

As described above, the first buffer layer 110 to the p-type cladding layer 126 can each be formed by a sputtering method. Therefore, the temperature during the film formation ranges from room temperature to a temperature less than 600° C., typically equal to or higher than 100° C. and equal to or lower than 400° C. Therefore, the plurality of light-emitting elements 100 can be manufactured using the substrate 102 containing inexpensive amorphous glass.

Furthermore, the gallium nitride layer 120 to the p-type cladding layer 126 are formed over the second buffer layer 112. Therefore, even though the vapor phase epitaxial growth conventionally used to form inorganic semiconductor layers is not applied, the semiconductor particles ejected by sputtering the semiconductor target are deposited to form each layer and are simultaneously induced to effectively orient in the c-axis direction by the second buffer layer 112. As a result, high temperatures are not required when the first buffer layer 110 to the p-type cladding layer 126 are formed, and each layer has high crystallinity, which allows the light-emitting element 100 to exhibit excellent characteristics as an LED.

### Third Embodiment

in this embodiment, a transistor according to an embodiment of the present invention is explained. An explanation of the structures the same as or similar to those described in the First and Second Embodiments may be omitted.

### 1. High Electron-Mobility Field-Effect Transistor

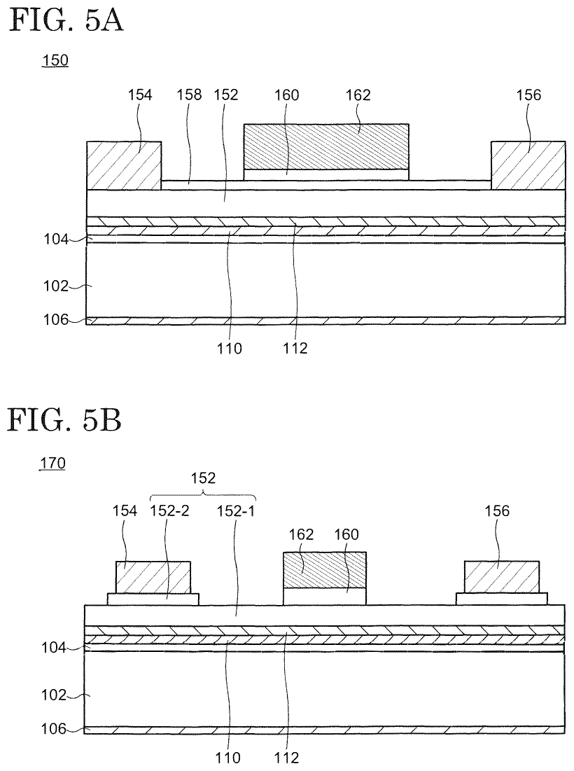

As an example of a transistor according to an embodiment of the present invention, a schematic cross-sectional view of a high electron-mobility field-effect transistor 150 is illustrated in FIG. 5A. The transistor 150 has a substrate 102 and includes a first buffer layer 110, a second buffer layer 112 over the substrate 102, and an active layer (also called an electron-travelling layer) 152 over the second buffer layer 112. The active layer 152 corresponds to the gallium nitride layer 120 of the light-emitting element 100 described in the First Embodiment. The transistor 150 further includes an electron-supplying layer 158 over the active layer 152 and a pair of terminals (a first terminal 154 and a second terminal 156) located over the active layer 152 and electrically connected to the active layer 152 and the electron-supplying layer 158. The first terminal 154 and the second terminal 156 may be in contact with the active layer 152 or may be connected to the active layer 152 via the electron-supplying layer 158. The transistor 150 further includes a gate electrode 162 which is in direct contact with the electron-supplying layer 158 or is provided over the electron-supplying layer 158 through an optionally arranged gate insulating film 160. Hereinafter, these components are described below. However, since the substrate 102, the overcoat 104, the undercoat 106, the first buffer layer 110, and the second buffer layer 112 are similar to those of the First Embodiment, the explanation thereof is omitted.

### (1) Active Layer and Electron-Supplying Layer

The stacking of the active layer 152 and the electron-supplying layer 158 creates a source/drain current path when the transistor 150 is driven. The active layer 152 and the electron-supplying layer 158 each include a Group 13 element and a Group 15 element. For example, the active layer 152 and the electron-supplying layer 158 may respectively include undoped gallium nitride and n-type aluminum gallium nitride. Alternatively, the active layer 152 and the electron-supplying layer 158 may respectively include undoped gallium arsenide (GaAs) and n-type aluminum gallium arsenide (AlGaAs). The active layer 152 is provided over and in contact with the second buffer layer 112 using a sputtering method. Therefore, the active layer 152 and the electron-supplying layer 158 can be formed even using the substrate 102 containing amorphous glass, since the film-formation at a high temperature required by epitaxial growth using MOCVD is not required. In addition, the crystallization of the active layer 152 and the electron-supplying layer 158 in the c-axis direction is promoted by the second buffer layer 112 acting as the base for the active layer 152 and the electron-supplying layer 158. Furthermore, as described in the First Embodiment, the second buffer layer 112 has high c-axis orientation because it is not directly provided over the substrate 102 having a large lattice mismatch, but over the first buffer layer 110 for mitigating the lattice mismatch. Therefore, even if a sputtering method is used to form the active layer 152 and the electron-supplying layer 158, high c-axis orientation can be achieved in these layers because the second buffer layer 112 also has high c-axis orientation. As a result, transistors with high field mobility can be provided.

### (2) First Terminal, Second Terminal, Gate Insulating Film, and Gate Electrode

The first terminal 154, the second terminal 156, and the gate electrode 162 include a metal such as aluminum, gold, silver, tantalum, molybdenum, titanium, and copper or an alloy containing one or a plurality of the above metals. The gate insulating film 160, which is an optional component, includes a silicon-containing inorganic compound such as silicon oxide and silicon nitride or a so-called high-k material such as hafnium silicate, zirconium silicate, hafnium oxide, and zirconium oxide. There are no restrictions on the method of forming these components, and a vacuum evaporation method, an electron beam evaporation method, a CVD method, and a sputtering method can be employed as appropriate. In particular, the first terminal 154, the second terminal 156, the gate insulating film 160, and the gate electrode 162 can be efficiently formed by using a sputtering method or an electron beam evaporation method having a high deposition rate.

### 2. Metal-Insulator Field-Effect Transistor

The transistor according to the present embodiment may be a so-called metal-insulator field-effect transistor (MISFET). For example, as demonstrated by the transistor 170 shown in FIG. 5B, the active layer 152 may be structured by a first active layer 152-1 including p-type gallium nitride and a second active layer 152-2 located over the first active layer 152-1 and including i-type or n-type gallium nitride without providing the electron-supplying layer 158. The second active layer 152-2 may be independently positioned between the first active layer 152-1 and the first terminal 154 and between the first active layer 152-1 and the second terminal 156, respectively, to form a source region and a drain region over the first active layer 152-1.

In the transistor 170, the active layer 152 determining the characteristics of the transistor 170 is also provided over the second buffer layer 112 which is provided over the first buffer layer 110 mitigating the lattice constant mismatch between the substrate 102 and the second buffer layer 112. Therefore, the c-axis orientation of the active layer 152 is promoted over the second buffer layer 112 whose c-axis orientation is improved by the first buffer layer 110, and as a result, the active layer 152 has high crystallinity. This feature allows the transistor 170 to have a high field mobility.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising:
a substrate including amorphous glass;
a first buffer layer located over the substrate and containing aluminum and oxygen;
a second buffer layer located over the first buffer layer and containing aluminum and nitrogen;
a gallium nitride layer over the second buffer layer;
a stack located over the gallium nitride layer and including an n-type cladding layer, a p-type cladding layer, and an emission layer between the n-type cladding layer and the p-type cladding layer; and
a cathode and an anode respectively located over the n-type cladding layer and the p-type cladding layer,
wherein each of the n-type cladding layer, the p-type cladding layer, and the emission layer contains a Group 13 element and a Group 15 element.

2. The light-emitting element according to claim 1,
wherein a thermal expansion coefficient of the first buffer layer is between thermal expansion coefficients of the substrate and the gallium nitride layer in an in-plane direction, and
a difference in lattice constant in an a-axis direction between the first buffer layer and the gallium nitride layer is smaller than that between the substrate and the gallium nitride layer.

3. The light-emitting element according to claim 2,
wherein the thermal expansion coefficient of the first buffer layer in the in-plane direction is equal to or greater than 3.5×10⁻⁶/° C. and equal to or less than 5.6×10⁻⁶/° C., and
the lattice constant of the first buffer layer in the a-axis direction is equal to or greater than 0.355 nm and equal to or less than 0.480 nm.

4. The light-emitting element according to claim 2,
wherein a thermal expansion coefficient of the second buffer layer is between the thermal expansion coefficients of the substrate and the gallium nitride layer in the in-plane direction, and
a difference in lattice constant in the a-axis direction between the second buffer layer and the gallium nitride layer is smaller than that between the substrate and the gallium nitride layer and smaller than that between the first buffer layer and the gallium nitride layer.

5. The light-emitting element according to claim 4,
wherein the thermal expansion coefficient of the second buffer layer in the in-plane direction is equal to or greater than 3.6×10⁻⁶/° C. and equal to or less than 4.6×10⁻⁶/° C., and
the lattice constant of the second buffer layer in the a-axis direction is equal to or greater than 0.300 nm and equal to or less than 0.330 nm.

6. The light-emitting element according to claim 1,
wherein the first buffer layer further contains nitrogen.

7. The light-emitting element according to claim 6,
wherein an oxygen concentration of the first buffer layer decreases with increasing distance from the substrate.

8. The light-emitting element according to claim 1,
wherein, in the second buffer layer, an atomic number ratio of nitrogen with respect to aluminum approaches 1 with increasing distance from the first buffer layer.

9. The light-emitting element according to claim 1, further comprising an undercoat containing aluminum nitride and/or aluminum oxide under the first substrate.

10. The light-emitting element according to claim 1,
wherein the gallium nitride layer is in direct contact with the second buffer layer.

11. A manufacturing method of a light-emitting element, the manufacturing method comprising:
forming a first buffer layer over a substrate containing amorphous glass;
forming a second buffer layer over the first buffer layer;
forming a gallium nitride layer over the second buffer layer with a sputtering method;
forming a stack including an n-type cladding layer, a p-type cladding layer, and an emission layer between the n-type cladding layer and the p-type cladding layer over the gallium nitride layer with a sputtering method; and
forming a cathode and an anode over the n-type cladding layer and the p-type cladding layer, respectively,
wherein each of the n-type cladding layer, the p-type cladding layer, and the emission layer contains a Group 13 element and a Group 15 element.

12. The manufacturing method according to claim 11,
wherein a thermal expansion coefficient of the first buffer layer is between thermal expansion coefficients of the substrate and the gallium nitride layer in an in-plane direction, and
a difference in lattice constant in an a-axis direction between the first buffer layer and the gallium nitride layer is smaller than that between the substrate and the gallium nitride layer.

13. The manufacturing method according to claim 12,
wherein the thermal expansion coefficient of the first buffer layer in the in-plane direction is equal to or greater than 3.5×10⁻⁶/° C. and equal to or less than 5.6×10⁻⁶/° C., and
the lattice constant of the first buffer layer in the a-axis direction is equal to or greater than 0.355 nm and equal to or less than 0.480 nm.

14. The manufacturing method according to claim 12,
wherein a thermal expansion coefficient of the second buffer layer is between the thermal expansion coefficients of the substrate and the gallium nitride layer in the in-plane direction, and
a difference in lattice constant in the a-axis direction between the second buffer layer and the gallium nitride layer is smaller than that between the substrate and the gallium nitride layer and smaller than that between the first buffer layer and the gallium nitride layer.

15. The manufacturing method according to claim 14,
wherein the thermal expansion coefficient of the second buffer layer in the in-plane direction is equal to or greater than 3.6×10⁻⁶/° C. and equal to or less than 4.6×10⁻⁶/° C., and
the lattice constant of the second buffer layer in the a-axis direction is equal to or greater than 0.300 nm and equal to or less than 0.330 nm.

16. The manufacturing method according to claim 11,
wherein the first buffer layer further contains nitrogen.

17. The manufacturing method according to claim 16,
wherein an oxygen concentration of the first buffer layer decreases with increasing distance from the substrate.

18. The manufacturing method according to claim 11,
wherein, in the second buffer layer, an atomic number ratio of nitrogen with respect to aluminum approaches 1 with increasing distance from the first buffer layer.

19. The manufacturing method according to claim 11, further comprising:
forming an undercoat containing aluminum nitride and/or aluminum oxide under the substrate.

20. The manufacturing method according to claim 11,
wherein the gallium nitride layer is in direct contact with the second buffer layer.
